(19) United States
(12) Patent Application Publication
(10) Pub. No.: US 2014/0104771 A1
(43) Pub. Date: Apr. 17, 2014

(54) Universal Keyless Entry System

(71) Applicant: Matthew A. COLAN, Elkhorn, NE (US)

(72) Inventor: Matthew A. COLAN, Elkhorn, NE (US)

(21) Appl. No.: 14/056,446

(22) Filed: Oct. 17, 2013

Related U.S. Application Data
(60) Provisional application No. 61/714,947, filed on Oct. 17, 2012.

(51) Int. Cl. G08C 17/02; H05K 5/02

(52) U.S. Cl. CPC G08C 17/02; H05K 5/0221
USPC 361/679.4; 361/809

(57) ABSTRACT

A universal keyless entry system that allows for multiple devices to be used to control functions of a vehicle. The universal keyless entry system includes an electronic device case, a fob, and a dongle. The electronic device case protects an electronic device, such as a smart phone, from impact forces, while also providing a docking station for the fob. In this way, an individual only needs to carry a single entity. The dongle plugs into a data port on the vehicle and allows both the fob and the electronic device to communicate with the vehicle in order to control functions of the vehicle. The electronic device can be used to program the fob, specifying which car functions are controlled by each button of the fob. In this way, the fob can be programmed as a valet remote or in any other way as desired by the individual.

The current application claims a priority to the U.S. Provisional Patent application Ser. No. 61/714,947 filed on Oct. 17, 2012.

### FIELD OF THE INVENTION

The present invention relates generally to a remote access system. More specifically, the present invention is a universal keyless entry system for a vehicle. Furthermore, the present invention includes a case in which a key fob synchronized to a car dongle is stored.

### BACKGROUND OF THE INVENTION

Keys have traditionally served as an integral component in motor vehicles, as they allow the vehicle engine to be turned on and off, as well as allow an individual to lock/unlock doors, glove compartments, trunks, etc. However, for many people car keys can provide a huge inconvenience, as they are often lost or misplaced. Countless hours are wasted in search of lost keys and often time departures are delayed due to lost or misplaced car keys. Additionally, keys are bulky and can be a hassle to carry. Many cars also have a key fob that is either integrated into the car key or used as a separate device. Key fobs allow an individual to remotely control functions of a car, such as lock/unlock doors or trigger the car alarm. While the features provided by the key fob are convenient, the key fob itself adds to the bulk that must be carried by the individual.

In an effort to minimize bulk and the occurrence of lost or misplaced car keys, software applications have been developed, allowing an individual to control functions of a vehicle from an electronic device, such as a mobile phone. This in turn eliminates the need to carry a key fob and/or car key. As most people carry their mobile phone with them regardless of the situation, the inconvenience of carrying an extra device is eliminated. Additionally, it is easier to find a misplaced mobile phone than a key or key fob, as an individual can call a mobile phone and listen for the mobile phone to ring.

While using an electronic device to control functions of a vehicle reduces the number of devices an individual must carry, a fault still lies in providing other people with access to a vehicle. If the owner of the vehicle wants to allow another individual access to the owner's vehicle, it is not always desirable for the owner to give his or her electronic device to the other individual. Cars are traditionally manufactured with a master key and a valet key. The master key provides access to all features of the car, while the valet car only allows the vehicle to be turned on or off. This functionality is not provided by current key fobs or through using an electronic device

Therefore it is the object of the present invention to provide a universal keyless entry system that allows for multiple devices to be used to control functions of a vehicle. The present invention includes an electronic device case, a fob, and a dongle. The electronic device case protects an electronic device, such as a smart phone, from impact forces, while also providing a docking station for the fob. In this way, an individual only needs to carry a single entity. The dongle plugs into a data port of the vehicle and allows both the fob and the electronic device to communicate with the vehicle in order to control functions of the vehicle. The electronic device can be used to program the fob, specifying which car functions are controlled by each button of the fob. In this way, the fob can be programmed as a valet remote or in any other way as desired by the individual.

### BRIEF DESCRIPTION OF THE DRAWINGS

FIG. 1 is a front perspective view of the electronic device case.

FIG. 2 is a front perspective view of the inner jacket.

FIG. 3 is a rear perspective view of the inner jacket.

FIG. 4 is a front perspective view of the outer shell.

FIG. 5 is a rear perspective view of the fob attached to the inner jacket and the inner jacket positioned within the outer shell.

FIG. 6 is a diagram depicting the wireless fob communication device being electrically connected to the battery.

FIG. 7 is a diagram depicting the wireless communication device being electronically connected to the triggering mechanism.

FIG. 8 is a front perspective view of the fob having the collapsible armature slid open.

FIG. 9 is a rear perspective view of the fob having the collapsible armature closed.

FIG. 10 is a diagram depicting the wireless dongle communication device being both electrically and electronically connected to the data plug.

FIG. 11 is a diagram depicting the flow of information between a communicably coupled fob, dongle, and electronic device.

FIG. 12 is a diagram depicting the fob being communicably coupled to the dongle through the wireless fob communication device and the wireless dongle communication device.

### DETAIL DESCRIPTIONS OF THE INVENTION

All illustrations of the drawings are for the purpose of describing selected versions of the present invention and are not intended to limit the scope of the present invention.

The present invention is a universal keyless entry system that allows an individual to remotely control functions of a vehicle. The universal keyless entry system comprises an electronic device case 1, a fob 4, and a dongle 5. The electronic device case 1 is used to hold an electronic device, such as a smart phone or tablet. The electronic device case 1 provides a barrier of protection around the electronic device, in addition to serving as a docking station for the fob 4. The fob 4 is able to communicate with the dongle 5, as well as the electronic device. When the fob 4 is docked within the electronic device case 1, the fob 4 functions as part of the electronic device and serves to protect the electronic device from any impact force.

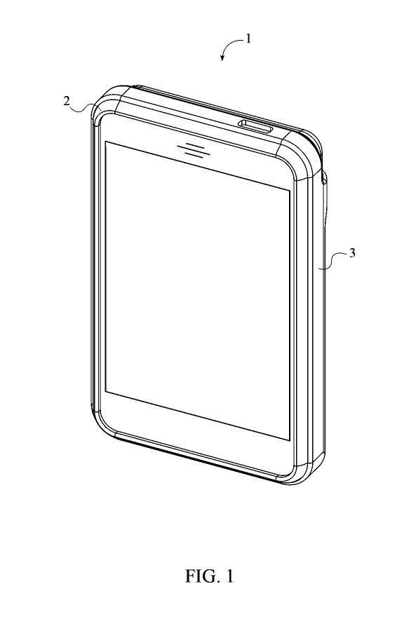

In reference to FIG. 1, the electronic device case 1 comprises an inner jacket 2 and an outer shell 3. In the preferred embodiment of the present invention, the inner jacket 2 is constructed from silicon and the outer shell 3 is constructed from polycarbonate; however, it is possible for the inner jacket 2 or the outer shell 3 to be constructed from any other material(s). Together, the inner jacket 2 and the outer shell 3 work to protect the electronic device from any impact forces. The outer shell 3 provides a rigid impact resistant cover, while the inner jacket 2 provides a flexible cover that helps to absorb shock from impact forces. The electronic device case 1 can be designed in any shape as to accommodate various types of electronic devices.

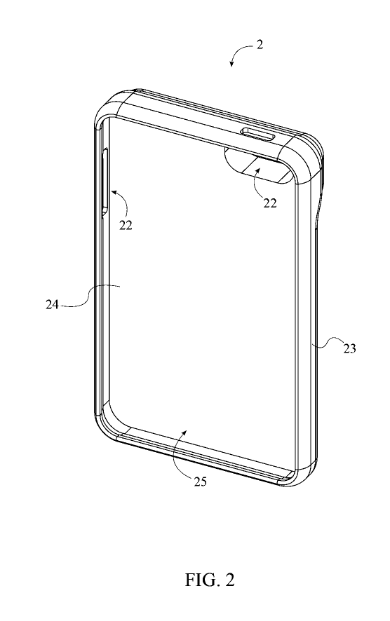

In reference to FIG. 2, the inner jacket 2 comprises a jacket back panel 24, a lateral jacket wall 23, a device receiving volume 25, a fob recess 21, and an at least one open jacket section 22. The lateral jacket wall 23 is perimetrically connected to the jacket back panel 24 in order to form the body of the inner jacket 2. Together, the jacket back panel 24 and the lateral jacket wall 23 delineate the device receiving volume 25. The device receiving volume 25 being the empty space in which the electronic device is positioned and held in place by the jacket back panel 24 and lateral jacket wall 23. The jacket back panel 24 rests flush against the electronic device, while the lateral jacket wall 23 runs flush around the sides of the electronic device. The lateral jacket wall 23 may additionally feature an extruded lip opposite the jacket back panel 24 to enhance the security of the electronic device within the inner jacket 2. The extruded lip extends over the device receiving volume 25, such that the electronic device is snapped in and out of place within the device receiving volume 25.

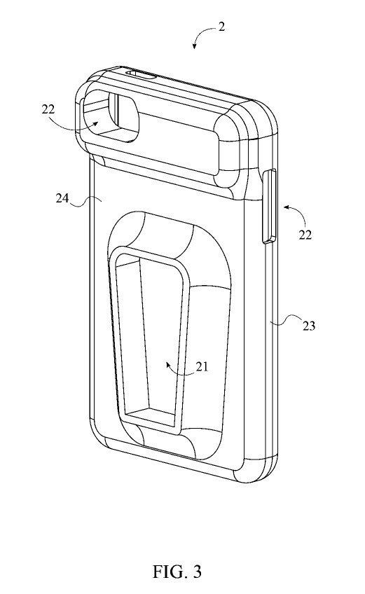

In reference to FIG. 3, in addition to holding an electronic device, the inner jacket 2 also provides the fob recess 21 as a docking station for retaining the fob 4. The fob recess 21 is centrally positioned across the jacket back panel 24 opposite the lateral jacket wall 23, such that the electronic device and fob 4 are housed opposite of one another in the inner jacket 2. The central positioning of the fob recess 21 is to minimize the bulkiness of the electronic device case 1 when the fob 4 is attached to the electronic device case 1. The fob 4 is held within the fob recess 21 by a frictional force that is created by the material surface of the inner jacket 2. When the fob 4 is positioned within the fob recess 21, the top surface of the fob 4 either rests flush with the back surface of the jacket back panel 24 or below the back surface of the jacket back panel 24. An extruded recess lip could also be positioned around the fob recess 21 to further secure the fob 4. The fob recess 21 can be designed to receive the fob 4 being any shape or size.

In reference to FIG. 2-3, the at least one open jacket section 22 can be positioned around the lateral jacket wall 23 and/or on the jacket back panel 24. The at least one open jacket section 22 allows a user to access hardware necessary for carrying out operations of the electronic device. For example, the at least one open jacket section 22 may be positioned on the jacket back panel 24 around a camera or speaker of the electronic device, such that the inner jacket 2 does not inhibit the use of the camera or speaker when the electronic device is positioned within the device receiving volume 25. Likewise, the at least one open jacket section 22 may be positioned on the lateral jacket wall 23 in order to provide an opening for a power switch, volume controls, shutter button, data port, etc.

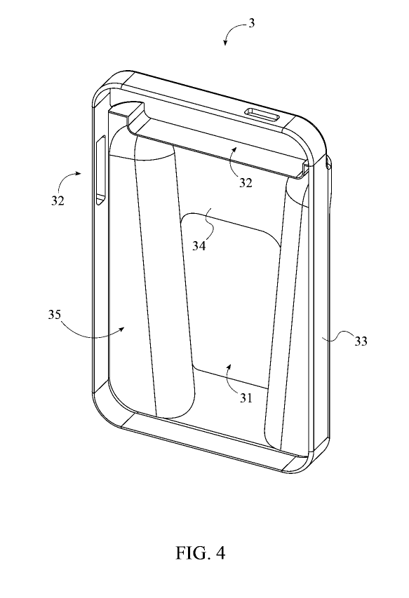

The outer shell 3 is attached to the inner jacket 2 by a frictional force, such that outer shell 3 of one design can be interchanged with the outer shell 3 of a different design. In reference to FIG. 4, the outer shell 3 comprises a shell back panel 34, a lateral shell wall 33, a jacket receiving volume 35, a recess opening 31, and an at least one open shell section 32. The lateral shell wall 33 is perimetrically connected to the shell back panel 34 in order to form the body of the outer shell 3. Together, the shell back panel 34 and the lateral shell wall 33 delineate the jacket receiving volume 35. The jacket receiving volume 35 being the empty space in which the inner jacket 2 is positioned and held in place by the shell back panel 34 and lateral shell wall 33. When the inner jacket 2 is positioned within the jacket receiving volume 35, the jacket back panel 24 is positioned flush against the shell back panel 34, while the lateral jacket wall 23 is positioned flush against the lateral shell wall 33.

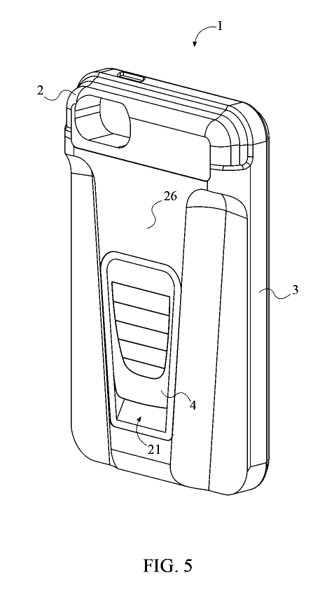

In reference to FIG. 5, when the outer shell 3 is attached to the inner jacket 2, the fob recess 21 is accessed through the recess opening 31. The recess opening 31 is centrally positioned across the jacket back panel 24 opposite the lateral jacket wall 23, such that the recess opening 31 is concentrically aligned with fob recess 21 Likewise, the at least one open shell section 32 is positioned around the at least one open jacket section 22. In this way, the hardware necessary for carrying out operations of the electronic device is accessible through both the at least one open shell section 32 and the at least one open jacket section 22.

In an alternative embodiment of the present invention, the inner jacket 2 further comprises a locking mechanism 26. The locking mechanism 26 is positioned adjacent to the fob recess 21 and comprises a release button and a stopper, the stopper being operatively coupled to the release button. Once the fob 4 is placed within the fob recess 21, the stopper engages the fob casing 41, preventing the fob 4 from being inadvertently removed from the fob recess 21. When the release button is pressed, the stopper disengages the fob casing 41, thus allowing the fob 4 to be removed from the fob recess 21. The release button is spring loaded and is accessible through a hole in the shell back panel 34.

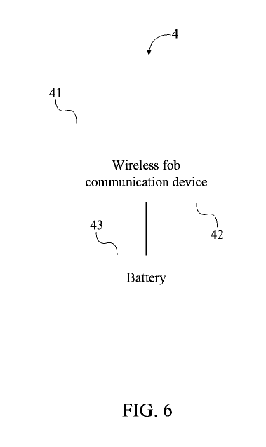

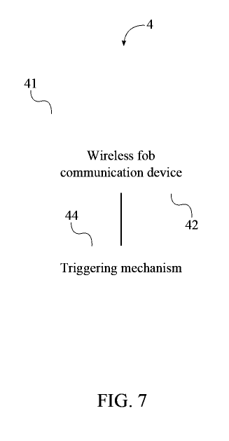

In reference to FIG. 6-7, the fob 4 is used to remotely control functions of a vehicle and comprises a fob casing 41, a wireless fob communication device 42, a battery 43, and a triggering mechanism 44. The fob casing 41 defines the shape of the fob 4 and is sized and shaped to fit within the fob recess 21. The fob casing 41 may also have a loop portion through which the fob 4 can be attached to a key ring, hung on a hook, etc. Both the wireless fob communication device 42 and the battery 43 are positioned fully within the fob casing 41. In the preferred embodiment of the present invention, the triggering mechanism 44 is at least one button that is positioned through the fob casing 41, such that the triggering mechanism 44 is accessible along the top surface of the fob casing 41. However, it is possible for the triggering mechanism to be any other device, such as a proximity sensor or touch screen. The battery 43 is electrically connected to the wireless fob communication device 42 in order to deliver current for powering the wireless fob communication device 42. The triggering mechanism 44 may also be electrically connected to the battery 43, if the triggering mechanism 44 is a device requiring electric current, such as proximity sensor or touch screen. The fob 4 may also comprise an access panel 45 that is attached to the fob casing 41, as shown in FIG. 9. The access panel 45 can be detached from the fob casing 41 in order to replace the battery 43 from within the fob casing 41 when necessary.

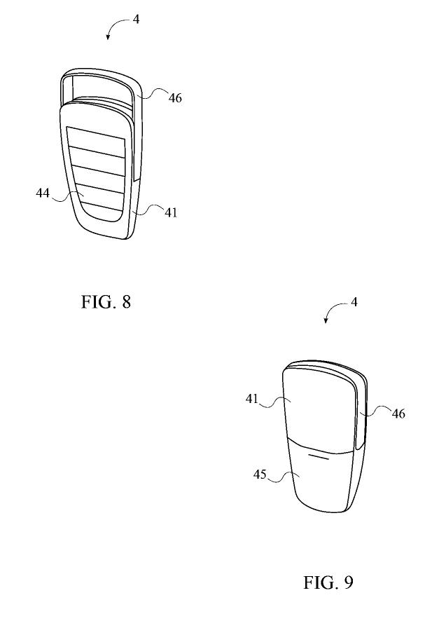

In one embodiment of the present invention, the fob 4 further comprises a collapsible armature 46, as shown in FIG. 8-9. The collapsible armature 46 is a U-shaped member that is slidably coupled to the fob casing 41. The two side arms of the collapsible armature 46 are positioned within tracks cut along opposite sides of the fob casing 41. In this way, the collapsible armature 46 can be slid along the tracks between a closed and open position. In the closed position, the collapsible armature 46 rests flush along the outer surface of the fob casing 41, such that the fob 4 takes up a smaller space for storage in a pocket or other container. In the open position, a loop is formed between the collapsible armature 46 and the adjacent side of the fob casing 41, allowing the fob 4 to be hung on or coupled to a hook, keychain, etc.

In order to use the fob 4, the wireless fob communication device 42 must be configured for a specific vehicle. In the preferred embodiment of the present invention, the wireless fob communication device 42 comprises a fob printed circuit board (PCB), a fob computing device, and a fob transceiver. The fob PCB electrically and electronically connects the fob computing device and the fob transceiver. Additionally the triggering mechanism 44 is electronically connected to the wireless fob communication device 42 through the fob PCB. The fob transceiver allows the fob 4 to communicate with both the electronic device of the user and the specific vehicle. A device driver unique to the specific vehicle is first downloaded on the electronic device of the user. The device driver is then transmitted to the fob 4 through the fob transceiver and stored on the fob computing device, thus allowing the fob 4 to communicate with and control the specific vehicle. Any wired or wireless programming device can be used to program the fob 4. The fob 4 further comprises a data port if the fob 4 is designed to be programmed by a wired programming device.

Once the device driver has been transmitted to the fob 4, a software application on the electronic device can be used to link vehicle functions to the triggering mechanism 44. For example, if the triggering mechanism is a set of buttons, then each button can be uniquely programmed for a specific vehicle command, such as starting or stopping the engine, locking or unlocking doors, opening the trunk, opening or closing windows, sounding the alarm, etc. The software application can also be used to directly send commands to the vehicle. The desired function for the triggering mechanism 44 is dictated by the user on the electronic device through the software application and then transmitted to the fob computing device through the fob transceiver. When the triggering mechanism 44 is activated, the fob computing device generates a signal used to control a function of the vehicle. Once the signal is generated, the signal is transmitted to the vehicle via the fob transceiver. The fob computing device also monitors the charge of the battery 43 and generates a signal, which is transmitted via the fob transceiver to the electronic device, such that the user can monitor the charge of the battery 43 on the electronic device.

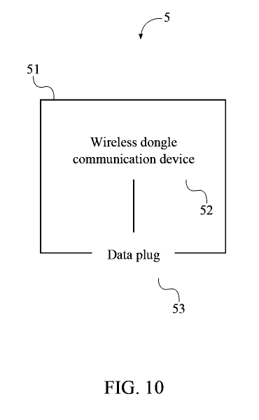

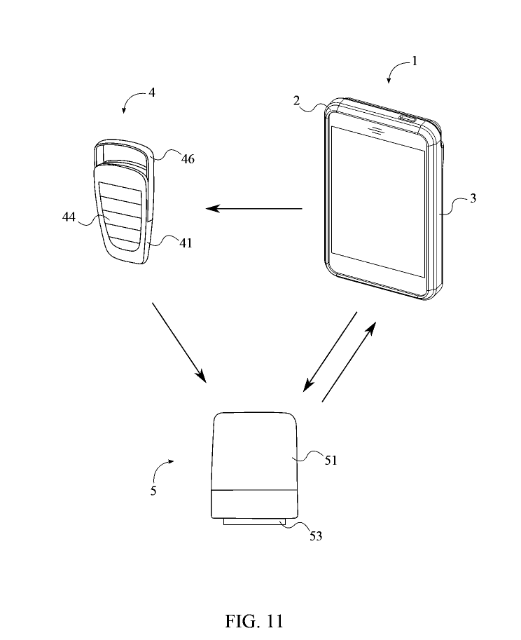

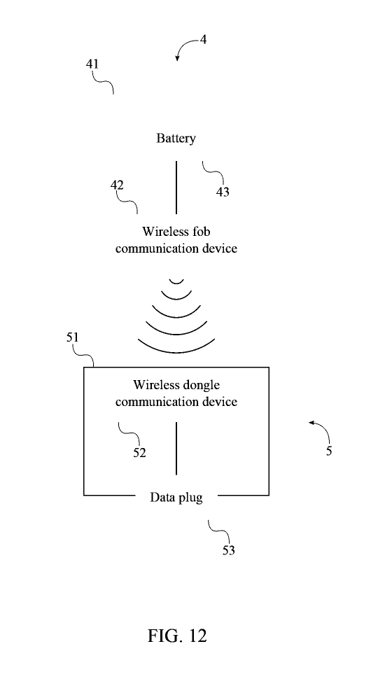

In reference to FIG. 10, communication between the fob 4 and specific vehicle is carried out through the dongle 5. The dongle 5 comprises a dongle casing 51, a wireless dongle communication device 52, and a data plug 53. The dongle casing 51 defines the shape of the dongle 5 and protects the wireless dongle communication device 52. The wireless dongle communication device 52 is fully positioned within the dongle casing 51, while the data plug 53 is partially positioned into the dongle casing 51, such that one end of the data plug 53 extends outwards from the dongle casing 51. In this way, the dongle 5 can be plugged into the data port of a vehicle via the data plug 53. The fob 4 is communicably coupled to the dongle 5 from the wireless fob communication device 42 to the wireless dongle communication device 52, as shown in FIG. 12.

The data plug 53 is electronically connected to the wireless dongle communication device 52, such that the wireless dongle communication device 52 can send electric signals to the on-board computer of the specific vehicle in order to control functions of the specific vehicle. Additionally, the data plug 53 is electrically connected to the wireless dongle communication device 52, such that the wireless dongle communication device 52 is powered by the specific vehicle. In the preferred embodiment of the present invention, the data plug 53 is designed to be compatible with an on-board diagnostics (OBD) port, such as an OBD-II port; however, the data plug 53 can be designed to be compatible with any other type of data port capable of supplying power to the wireless dongle communication device 52, such as a Universal Serial Bus (USB) port.

In the preferred embodiment of the present invention, the wireless dongle communication device 52 comprises a dongle PCB, a dongle computing device, and a dongle transceiver. The dongle PCB electrically and electronically connects the dongle computing device and the dongle transceiver. The dongle transceiver allows the dongle 5 to communicate with both the fob 4 and the electronic device of the user. In this way, signals transmitted from either the fob 4 or the electronic device are received by the dongle transceiver and relayed to the dongle computing device. The dongle computing device then generates a signal to control a function of the specific vehicle that is sent to the on-board computer of the specific vehicle via the data plug 53. The dongle transceiver also allows the dongle 5 to transmit signals to the electronic device in order to monitor the status of the specific vehicle.

Depending on the vehicle, the dongle 5 may be permanently or non-permanently affixed to the vehicle in order for the fob 4 and the electronic device to be able to communicate with the vehicle. If the present invention is intended to be used with a pre-existing vehicle, then the dongle 5 is non-permanently plugged into a data port of the vehicle in order to allow the fob 4 and the electronic device to communicate with the pre-existing vehicle. If the present invention is integrated into a new vehicle, then the dongle 5 can be permanently installed in the new vehicle at the time of manufacture. The fob 4 is then also built and programmed by the manufacturer.

In reference to FIG. 11, any type of wireless communication standard can be utilized by the fob 4, the electronic device, and the dongle 5 or vehicle, such as radio frequency communication including radio frequency identification (RFID) and near field communication (NFC). RFID and NFC standards may be beneficial for communication between the fob 4 and electronic device when both the fob 4 and electronic device are housed within the electronic device case 1. Conversely, long range radio frequency communication standards would allow for communication between the dongle 5 and the fob 4 or electronic device in order to control functions of the vehicle, such as locking or unlocking doors, opening the trunk, etc.

In one embodiment, the present invention further comprises a fob charger. The fob charger allows the fob 4 to be charged by an electrical port of the vehicle and comprises a fob port and a charger plug. The charger plug is inserted into the electrical port of the vehicle, such as a USB or OBD-II port. The fob 4 is then inserted into the fob port and in turn is charged by the vehicle battery. The fob charger could also be designed with electrical prongs, such that the fob charger could be used to charge the fob 4 in an individual's home.

Although the present invention is intended for use with a vehicle, the universal keyless entry system can be adapted for use with any other type of lock mechanism. For example, the fob 4 could be synchronized with an electronic locking mechanism of a home door. An individual could then lock/unlock the home door using either the fob 4 or the electronic device. It is also possible in other embodiments of the present invention for the fob 4 to be programmed to communicate with more than one electronic device. For example, the fob 4 could be communicably coupled to more than one dongle 5, or used to control both a vehicle and the electronic locking mechanism of a home door. The user can then use the fob 4 and/or the electronic device as a universal key for multiple locks as opposed to carrying several keys for several devices.

Although the invention has been explained in relation to its preferred embodiment, it is to be understood that many other possible modifications and variations can be made without departing from the spirit and scope of the invention as hereinafter claimed.

What is claimed is:

1. An keyless entry system comprises:
an electronic device case;
the electronic device case comprises an inner jacket and an outer shell;
the inner jacket comprises a fob recess, an at least one open jacket section, a lateral jacket wall, a jacket back panel, and a device receiving volume;
the outer shell comprises a recess opening, an at least one open shell section, a lateral shell wall, a shell back panel, and a jacket receiving volume;
the lateral jacket wall being perimetrically connected to the jacket back panel;
the device receiving volume being delineated by the jacket back panel and the lateral jacket wall;
the fob recess being centrally positioned across the jacket back panel opposite the lateral jacket wall;
the lateral shell wall being perimetrically connected to the shell back panel;
the jacket receiving volume being delineated by the shell back panel and the lateral shell wall; and
the recess opening being centrally positioned across the shell back panel.

2. The keyless entry system as claimed in claim 1 comprises:
the outer shell being attached to the inner jacket;
the inner jacket being positioned within the jacket receiving volume;
the lateral jacket wall being positioned flush against the lateral shell wall;
the jacket back panel being positioned flush against the shell back panel;
the recess opening being concentrically aligned with the fob recess; and
the at least one open shell section being positioned around the at least one open jacket section.

3. The keyless entry system as claimed in claim 1 comprises:
the at least one open jacket section being positioned on the lateral jacket wall; and
the at least one open shell section being positioned on the lateral shell wall.

4. The keyless entry system as claimed in claim 1 comprises:
the at least one open jacket section being positioned on the jacket back panel; and
the at least one open shell section being positioned on the shell back panel.

5. The keyless entry system as claimed in claim 1 comprises:
a fob;
the fob comprises a fob casing, a wireless fob communication device, a battery, and a triggering mechanism, wherein the wireless fob communication device allows the fob to communicate with a multitude of electronic devices;
the wireless fob communication device and the battery being positioned within the fob casing;
the wireless fob communication device being electrically connected to the battery; and
the triggering mechanism being electronically connected to the wireless communication device.

6. The keyless entry system as claimed in claim 5 comprises:
the fob being attached to the inner jacket; and
the fob being positioned within the fob recess.

7. The keyless entry system as claimed in claim 5 comprises:
the fob further comprises an access panel; and
the access panel being attached to the fob casing, wherein the access panel can be removed in order to access the wireless fob communication device and the battery.

8. The keyless entry system as claimed in claim 5 comprises:
the fob further comprises a collapsible armature; and
the collapsible armature being slidably coupled to the fob casing.

9. The keyless entry device as claimed in claim 1 comprises:
a dongle;
the dongle comprises a dongle casing, a wireless dongle communication device, and a data plug;
the wireless dongle communication device being positioned within the dongle casing;
the data plug being positioned into the dongle casing;
the data plug being electronically connected to the wireless dongle communication device; and
the data plug being electrically connected to the wireless dongle communication device.

10. The keyless entry system as claimed in claim 1 comprises:
the inner jacket comprises a locking mechanism; and
the locking mechanism being positioned adjacent to the recess opening.

11. An keyless entry system comprises:
an electronic device case;
a fob;
a dongle;
the electronic device case comprises an inner jacket and an outer shell;
the fob comprises a fob casing, a wireless fob communication device, a battery, and a triggering mechanism, wherein the wireless fob communication device allows the fob to communicate with a multitude of electronic devices;
the dongle comprises a dongle casing, a wireless dongle communication device, and a data plug;
the inner jacket comprises a fob recess, an at least one open jacket section, a lateral jacket wall, a jacket back panel, and a device receiving volume;
the outer shell comprises a recess opening, an at least one open shell section, a lateral shell wall, a shell back panel, and a jacket receiving volume;
the lateral jacket wall being perimetrically connected to the jacket back panel;
the device receiving volume being delineated by the jacket back panel and the lateral jacket wall;
the fob recess being centrally positioned across the jacket back panel opposite the lateral jacket wall;
the lateral shell wall being perimetrically connected to the shell back panel;
the jacket receiving volume being delineated by the shell back panel and the lateral shell wall;
the recess opening being centrally positioned across the shell back panel; and
the fob being communicably coupled to the dongle from the wireless fob communication device to the wireless dongle communication device.

12. The keyless entry system as claimed in claim 11 comprises:
the outer shell being attached to the inner jacket;
the inner jacket being positioned within the jacket receiving volume;
the lateral jacket wall being positioned flush against the lateral shell wall;
the jacket back panel being positioned flush against the shell back panel;
the recess opening being concentrically aligned with the fob recess; and
the at least one open shell section being positioned around the at least one open jacket section.

13. The keyless entry system as claimed in claim 11 comprises:
the at least one open jacket section being positioned on the lateral jacket wall;
and the at least one open shell section being positioned on the lateral shell wall.

14. The keyless entry system as claimed in claim 11 comprises:
the at least one open jacket section being positioned on the jacket back panel; and
the at least one open shell section being positioned on the shell back panel.

15. The keyless entry system as claimed in claim 11 comprises:
the fob being attached to the inner jacket; and
the fob being positioned within the fob recess.

16. The keyless entry system as claimed in claim 11 comprises:
the wireless fob communication device and the battery being positioned within the fob casing;
the wireless fob communication device being electrically connected to the battery; and
the triggering mechanism being electronically connected to the wireless fob communication device.

17. The keyless entry system as claimed in claim 11 comprises:
the fob further comprises an access panel; and
the access panel being attached to the fob casing, wherein the access panel can be removed in order to access the wireless fob communication device and the battery.

18. The keyless entry system as claimed in claim 11 comprises:
the fob further comprises a collapsible armature; and
the collapsible armature being slidably coupled to the fob casing.

19. The keyless entry system as claimed in claim 11 comprises:
the wireless dongle communication device being positioned within the dongle casing;
the data plug being positioned into the dongle casing;
the data plug being electronically connected to the wireless dongle communication device; and
the data plug being electrically connected to the wireless dongle communication device.

20. The keyless entry system as claimed in claim 11 comprises:
the inner jacket comprises a locking mechanism; and
the locking mechanism being positioned adjacent to the recess opening.
